(19) United States
(12) Patent Application Publication
(10) Pub. No.: US 2013/0132806 A1
(43) Pub. Date: May 23, 2013

(54) Convolutional Turbo Code Decoding in Receiver With Iteration Termination Based on Predicted Non-Convergence

(71) Applicants: Shashidhar VUMMINTALA, Bangalore (IN); Prakash NARAYANAMOORTHY, Bangalore (IN); Abir MOOKHERJEE, Bangalore (IN)

(72) Inventors: Shashidhar VUMMINTALA, Bangalore (IN); Prakash NARAYANAMOORTHY, Bangalore (IN); Abir MOOKHERJEE, Bangalore (IN)

(73) Assignee: Broadcom Corporation, Irvine, CA (US)

(21) Appl. No.: 13/341,294

(22) Filed: Dec. 30, 2011

Related U.S. Application Data
(60) Provisional application No. 61/562,196, filed on Nov. 21, 2011.
(60) Provisional application No. 61/576,225, filed on Dec. 15, 2011.

(51) Int. Cl. H03M 13/09; G06F 11/10

(52) U.S. Cl. 714/800; 714/E11.032

(57) ABSTRACT

This disclosure introduces the concept of a strategy for a Convolutional Turbo Code decoder to make a prediction with regards to the likelihood of convergence. If a failure of convergence appears likely, the decoding process is aborted, The predictions regarding failure of convergence are made at the end of each half-iteration in a decoding process, leading to more efficient use of decoders in a system.

### CROSS-REFERENCE TO RELATED APPLICATIONS

The present application claims the benefit of U.S. Provisional Patent Appl. No. 61/562,196, filed Nov. 21, 2011, and U.S. Provisional Patent Appl. No. 61/576,225, filed Dec. 15, 2011, each of which is incorporated herein by reference in its entirety.

### BACKGROUND OF THE DISCLOSURE

1. Field of the Disclosure

The disclosure relates generally to the field of communication, and more particularly to improved decoding strategies based on prediction of non-convergence of bits from transmitted code blocks.

2. Related Art

Conventional modems have a standard defined maximum limit of Convolutional Turbo Code (CTC) decoder iterations. Turbo codes are a class of high-performance forward error correction (FEC) codes which were the first practical codes to closely approach the channel capacity, a theoretical maximum for the code rate at which reliable communication is still possible given a specific noise level. Turbo codes are decoded using a convolution method where for each transmission, decoders attempt to iteratively decode each bit of a transmission over a number of iterations. Conventionally, the upper limit to decode is eight iterations, but as little as four iterations may be used at a cost of sacrificing performance. However, in greater than 10-20%, sometimes as high as 50% depending upon system configuration, of instances of decoding, more than eight iterations would be required to decode each bit of the transmission. Thus, when a conventional CTC decoder reaches the upper limits of eight iterations without converging, the decoding process terminates without ever having identified the underlying valid code block or code word. Therefore, the eight conducted iterations are an inefficient use of time and resources, leading to inefficiency in a respective receiver.

Therefore, what is needed is a method to increase the efficiency of a Turbo Code decoder that overcomes the shortcomings described above. Further aspects and advantages of the present disclosure will become apparent from the detailed description that follows.

### BRIEF DESCRIPTION OF THE DRAWINGS/FIGURES

The accompanying drawings, which are incorporated herein and form a part of the specification, illustrate the present disclosure and, together with the description, further serve to explain the principles of the disclosure and to enable a person skilled in the pertinent art to make and use the disclosure.

FIG. 1 illustrates an exemplary block diagram of a communication system according to an exemplary embodiment of the present disclosure; and

FIG. 2 is a flowchart of exemplary operational steps for decoding a sequence of data according to an exemplary embodiment of the present disclosure.

### DETAILED DESCRIPTION

In the following description, numerous specific details are set forth in order to provide a thorough understanding of the disclosure. However, it will be apparent to those skilled in the art that the disclosure, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring aspects of the disclosure.

References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described.

The present disclosure will now be described with reference to the accompanying drawings. In the drawings, like reference numbers indicate identical or functionally similar elements. Additionally, the left-most digit(s) of a reference number identifies the drawing in which the reference number first appears.

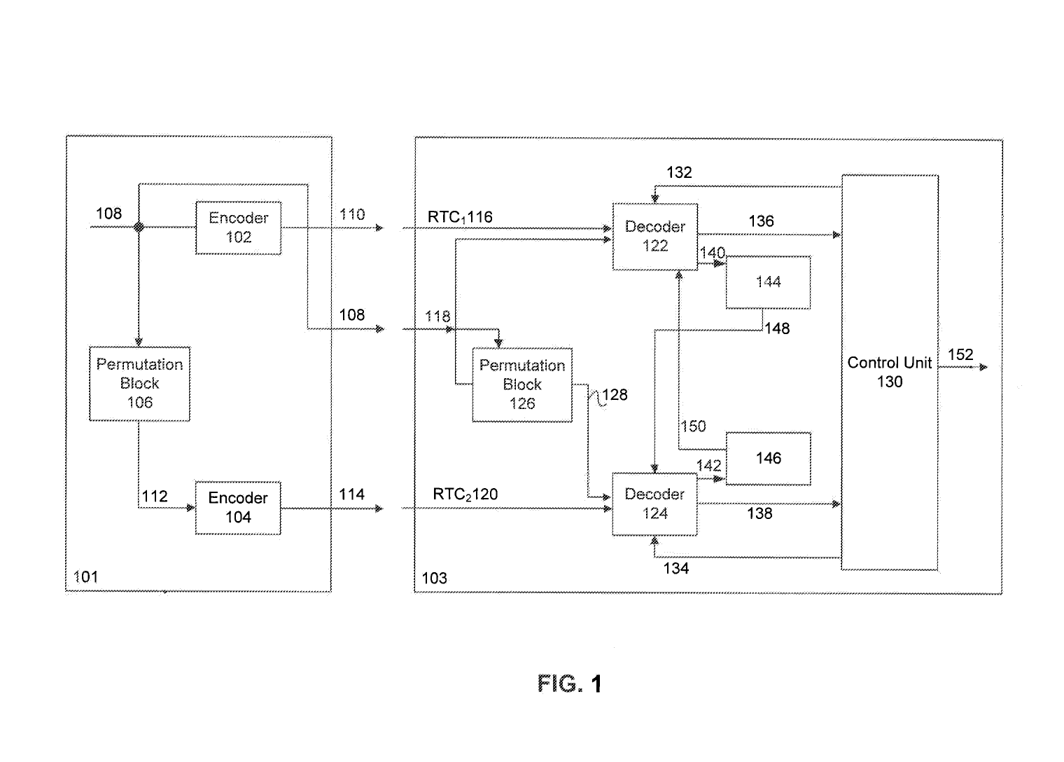

FIG. 1 illustrates a block diagram of a communication system according to an exemplary embodiment of the present disclosure. As shown in FIG. 1, the communication system includes a transmitter 101 and a receiver 103. The transmitter 101 includes encoders 102 and 104 and a permutation block 106.

The encoders 102 and 104 implement turbo coding of a sequence of data 108 and a sequence of permutated data 112, respectively, which may be utilized for reliable and successful transmission of the sequence of data 108 from a transmitter 101 to the receiver 103. The sequence of data 108 may represent one or more codeblocks from among multiple codeblocks of a data packet. For example, a data packet may include ten code blocks each of the code blocks containing twenty bits. Typically, the encoders 102 and 104 are collectively configured to implement a turbo code. The encoders 102 and 104 may be configured to implement same or different constituent encoders of the turbo code. The permutation block 106 provides a randomized version of the sequence of data 108 to the encoder 104 as the sequence of permutated data 112. For example, the permutation block 106 may interleave the sequence of data 108 to provide the sequence of permutated data 112. The encoder 102 outputs a first parity sequence, denoted as first Turbo Code (TC₁) 110, and the encoder 104 outputs a second parity sequence, denoted as a second Turbo Code (TC₂) 114, which both represent encoded turbo code generated based on the sequence of data 108.

The transmitter 101 thereafter transmits the sequence of data 108, the TC₁ 110 and the TC₂ 114 to the receiver 103. By way of example, the sequence of data 108, the TC₁ 110 and the TC₂ 114 together include a total of 30 data bits which may be broken down into 10 data bits belonging to sequence of data 108 and 20 additional overhead data bits comprising TC₁ 110 and TC₂ 114.

The receiver 103 respectively receives a sequence of received data 118, a first Received Turbo Code (RTC₁) 116, and a second Received Turbo Code (RTC₂) 120. Ideally, the sequence of received data 118, the RTC₁ 116, and the RTC₂ 120 represent the sequence of data 108, the TC₁ 110, and TC₂ 114, respectively. However, in practice, the transmission process may degrade the sequence of data 108, the TC₁ 110 and/or the TC₂ 114 causing the sequence of received data 118, the RTC₁ 116 and/or the RTC₂ 120 to be different. For example, a communication channel contains a propagation medium that the sequence of data 108, the TC₁ 110, and TC₂ 114 pass through before reception by the receiver 103. The propagation medium of the communication channel introduces interference and/or distortion into the sequence of data 108, the TC₁ 110 and/or TC₂ 114 causing the sequence of received data 118, the RTC₁ 116 and/or the RTC₂ 120 to differ.

The receiver 103 includes decoders 122 and 124, permutations block 126 and 144, a control unit 130, and an inverse-permutation permutation block 146. The permutation block 126 forces the randomization of the sequence of received data 118 to provide a sequence of permutated data 128 allowing for two turbo codes to be transmitted which can be verified with each to decode data. Typically, the permutation block 126 is substantially similar to the permutation block 106.

The sequence of received data 118 and the RTC₁ 116 are provided to the decoder 122. Likewise, the sequence of permutated data 128 and the RTC₂ 120 are provided to the decoder 124. The decoders 122 and 124 are configured to decode the sequence of received data 118 and the sequence of permutated data 128, respectively. The decoder 122 outputs a first set of decoded log likelihood ratios (LLRs) 136 that are provided to the control unit 130. The decoder 124 outputs a second set of decoded LLRs 138 that are provided to the control unit 130.

Each LLR in the respective first and second sets of decoded LLRs 136 and 138 represents a probability for each bit in a code block regarding whether that particular bit is a 1 or a 0. The LLR of each bit in a code block is calculated as follows:

$$LLR = log ( \frac{P ( 1 )}{P ( 0 )} ) , \qquad ( 1 )$$

where P(1) represents a probability of a bit from among RTC₁ 116 and/or RTC₂ 120 being a logical one and P(0) represents a probability of a bit from among RTC₁ 116 and/or RTC₂ 120 being a logical zero. It should be noted that various well known algorithms may be used to calculate this probability.

The decoder 122 and the decoder 124 provide sequences of extrinsic information 140 and 142, respectively. The sequences of extrinsic information 140 and the extrinsic information 142 are passed onto the decoder 124 and the decoder 122, respectively. For example, after a first half-iteration in the decoding process, the sequence of extrinsic information 142 may be passed to the decoder 122. The decoder 122 would utilize the sequence of extrinsic information 142 to decode the sequence of received data 118 and provide a next set of decoded LLRs 136. The sequences of extrinsic information 140 and 142 represent additional information provided by the decoder 122 and decoder 124, respectively, for use by the decoder 124 and the decoder 122 for the decoding process. For example, the sequence of extrinsic information 142 can be obtained in a current half-iteration as a difference between a second set of decoded LLRs 138 and a combination of the sequence of permutated data 128 and a sequence of extrinsic information 148. As another example, the example, the sequence of extrinsic information 140 can be obtained in a current half-iteration as a difference between a first set of decoded LLRs 136 and a combination of the sequence of received data 118 and a sequence of extrinsic information 150.

The permutation block 144 provides the sequence of extrinsic information 148 to the decoder 124. The permutation block 144 forces the randomization of the sequence of extrinsic information 140 to provide the sequence of extrinsic information 148. Typically, the permutation block 144 randomizes the sequence of extrinsic information 140 in a substantially similar manner as the permutation block 126 randomizes the sequence of received data 118.

The inverse-permutation block 146 negates the overall effect of permutations of the sequence of extrinsic information 142 to provide the sequence of extrinsic information 150 to the decoder 122.

In an embodiment, either decoder 122 or decoder 124 may perform a first half-iteration in a CTC decoding process. There is no extrinsic information provided to the decoder conducting the first half-iteration in the CTC decoding process. Thereafter, the decoder that provides a set of decoder LLRs to the control unit 130 may also provide extrinsic information to the other decoder to aid in conducting the next half-iteration.

The control unit 130 manages the decoders 122 and 124 utilizing respective control signals 132 and 134 to enable decoding in the decoders 122 and 124. The control unit 130 calculates the mean magnitudes of the first set of decoded LLRs 136 and the second set of decoded LLR 138 at each half-iteration. Alternatively, the control unit 130 may calculate these mean magnitudes after a predetermined number of iterations. A mean magnitude takes into account the LLR of each of the bits in a decoded code block that is outputted by a respective decoder. For example, at the end of a half-iteration at decoder 124, the mean magnitude takes into account all the outputted decoded LLRs from the second set of LLRs 138. The mean magnitude is calculated by summing up the magnitude of each outputted decoded LLR after a half-iteration and dividing it by the number of LLRs (decoded bits) in the respective half-iteration. Typically, the control unit 130 calculates the mean magnitudes

The comparison of mean magnitudes of a current or latest half-iteration with a previous half iteration occurs after a certain amount of iterations. The amount of iterations after which mean magnitudes are compared is dependent on user choice or pre-defined conditional criteria, such as a pre-defined code rate, operating signal to noise ratio (SNR) to provide some examples.

In an embodiment, as an example, a CTC decoder iteration comprises providing an input sequence of received data 118 to decoder 122. The decoder 122 decodes the inputted sequence of received data 118 utilizing RTC₁ 116 and provides an output 136. The decoder 124 may utilize input sequence of received data 118, sequence of permutated data 128 and RTC₂ 120 to provide an output 138. The output 138 by the second decoder 124 completes an iteration that begins with the input of RC₁ 116 in decoder 122.

Additionally, the control unit 130 provides a sequence of decoded data 152 once successful decoding of a code block occurs.

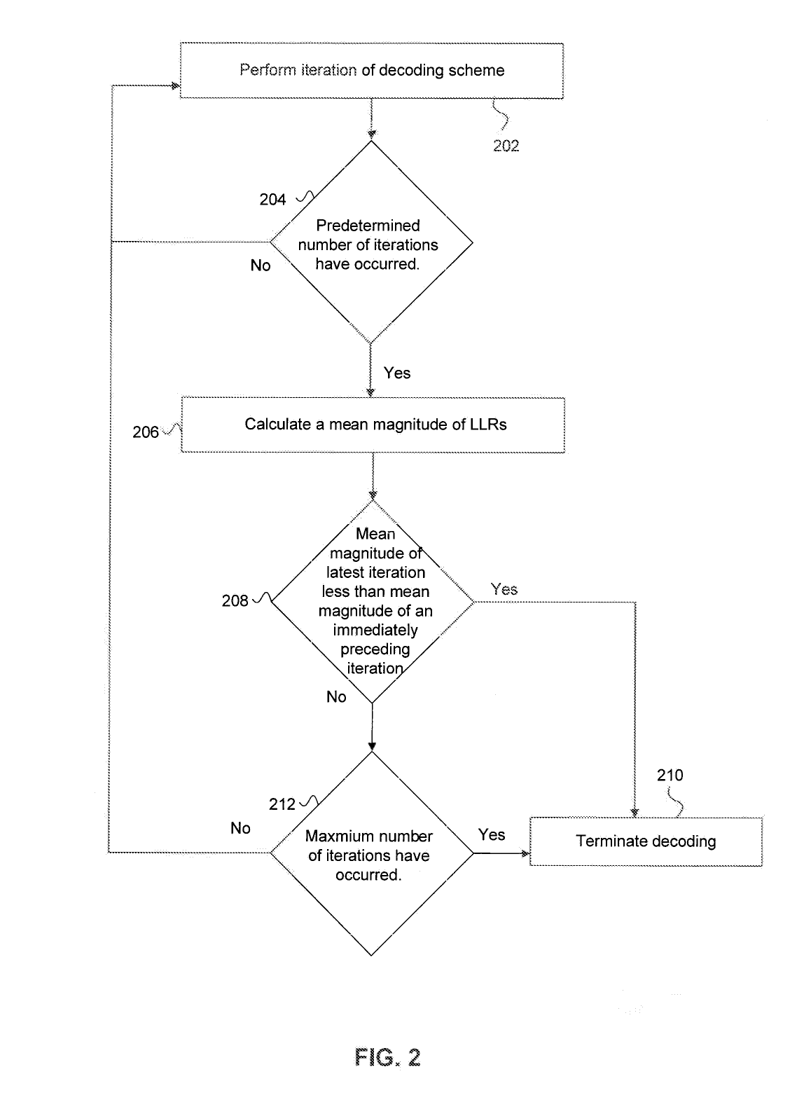

The details regarding the calculation of the mean magnitudes of LLRs of a code block and its comparison to terminate decoding is presented in further detail in FIG. 2 and the explanation presented below. In an embodiment, the control unit 130 (or another processor with similar functionality) may function to carry out the steps of the flowchart presented in FIG. 2.

FIG. 2 is a flowchart of exemplary operational steps for decoding a sequence of data according to an exemplary embodiment of the present disclosure. The disclosure is not limited to this operational description. Rather, it will be apparent to persons skilled in the relevant art(s) from the teachings herein that other operational control flows are within the scope and spirit of the present disclosure. The following discussion describes the steps in FIG. 2.

At step 202, the operational control flow performs an iteration of a decoding scheme to decode a sequence of data, such as a code block to provide an example. Typically, the operational control flow performs a complete iteration of a turbo decoding scheme at step 202. The complete iteration of the turbo decoding scheme typically involves performing a first half-iteration to determine a first set of LLRs and a second half-iteration to determine a second set of LLRs.

At step 204, the operation control flow determines whether a pre-determined number of iterations of the decoding scheme have occurred. If so, the operation control proceeds to step 206, otherwise the operation control flow reverts to step 202 to perform another iteration.

At step 206, the operational control flow calculates a mean magnitude of LLRs in the sequence of data. In an exemplary embodiment, the operational control flow calculates the mean magnitude of LLRs in the sequence of data at the end of the half-iterations of the turbo decoding scheme. In this exemplary embodiment, the operational control flow may calculate the mean magnitude of the first set of LLRs at the end of the first half-iteration and/or the mean magnitude of the second set of LLRs at the end of the second half-iteration.

At step 208, the operation control flow compares the mean magnitude of LLRs from step 206 to a mean magnitude of an immediately preceding iteration. Alternatively, the operation control flow may compare the mean magnitude of LLRs of the latest half-iteration to a mean magnitude of an immediately preceding half-iteration. The operation control flow proceeds to step 210 when the mean magnitude of LLRs from step 206 is less than the mean magnitude of the immediately preceding iteration. Otherwise, the operation control flow proceeds to step 212.

At step 210, the operational control flow terminates decoding of the sequence of data and, optionally, may request retransmission of the sequence of data.

At step 212, the operational control flow determines whether a maximum number of iterations, or half-iterations, of have occurred. Typically, the operational control flow maintains a count of a number of iterations, or half-iterations, that have been undertaken for a given sequence of data. The operational control flow compares this count to a threshold indicative of the maximum number of iterations in step 212. If the maximum number of iterations of has occurred, the operational control flow reverts to step 210. Otherwise, the operational control flow reverts to step 202 to perform another iteration.

Essentially, the predictive process is an attempted calculation to determine whether a bit value of each of bit of the code word is converging towards a logical one or a logical zero. The use of the log function, allows the difference to be a more pronounced and visible difference. Due to the LLRs being derived using a log function, an increase in the mean magnitude from a previous iterations means that that probability of a bit being logical one or a logical zero is converging. However, if the mean magnitude compared to a previous iteration is lower, it indicates that the probability of a bit being a logical one or a logical zero is not converging. If the number of times this occurs exceeds a threshold level, it is likely that there will be no convergence by the predetermined number of iterations, due to multiple indications that there may not be convergence. Accordingly, decoding of the code block is terminated and resources (e.g. processor time, power) are saved from unnecessary usage. The preserved resources are then free and can be utilized when the codeblock is retransmitted, leading to an overall more efficient system.

Even though the disclosure has been described in terms of using the mean magnitude to detect for the convergence of the decoding scheme, those skilled in the relevant art(s) will recognize that other measures of the LLRs may be used to detect for the convergence of the decoding scheme without departing from the spirit and scope of the present disclosure. For example, the number of bits that were toggled across more than one iteration may be examined and a decrease in this number may be used as an indication of whether the decoding scheme is converging.

In an embodiment, the determination of probability of a bit being a logical one or a logical zero to calculate LLRs may take into account data from the preceding determinations and output from a respective decoder (122 or 124) conducting the previous half-iteration.

In an embodiment, at every re-transmission (starting from the fresh transmission), if any decoding of a codeblock of a packet is terminated early due to predicted non-convergence, all decoding of remaining codeblocks in the packet is terminated. The counterparts of the transmitted bits in a code block are then attempted to be decoded in the next retransmission.

In another embodiment, extrinsic information outputted by respective decoders may be replaced with total apriori information. In such an arrangement, outputted decoded LLRs would be provided to the control unit and the parallel decoder. The parallel decoder would process the information for decoding the decoders based on the set of decoded LLRs that are outputted for its corresponding parallel decoder in that respective decoder's previous half-iteration.

Embodiments of the disclosure may be implemented in hardware, firmware, software, or any combination thereof. Embodiments of the disclosure may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

The breadth and scope of the present disclosure should not be limited by any of the above-described exemplary embodiments, but should be defined only in accordance with the following claims and their equivalents.

What is claimed is:

1. An apparatus for decoding a received code word, comprising:
a first decoder configured to provide a first decoded log likelihood ratio (LLR) and first extrinsic information based upon the received code word, a first parity sequence, and second extrinsic information;
a second decoder configured to provide a second decoded LLR and the second extrinsic information based upon the received code word, a second parity sequence, and the first extrinsic information; and
a control unit configured to compare a measure of the first decoded LLR to a previous measure of the first decoded LLR and to compare a measure of the second decoded LLR to a previous measure of the second decoded LLR to determine whether the first decoded LLR and the second decoded LLR are converging and to terminate decoding of the received code word when differences between the measures of the first and second decoded LLRs and the previous measures of the first and second decoded LLRs, respectively, indicate that the first and second decoded LLRs are not converging.

2. The apparatus of claim 1, wherein the measure of the first and second decoded LLRs and the previous measures of the first and second decoded LLRs are mean magnitudes of the first and second decoded LLRs and previous first and second decoded LLRs, respectively.

3. The apparatus of claim 2, wherein the control unit is further configured to combine a LLR for each bit in the first decoded LLR and divide by a first number of bits in the first decoded LLR to determine the mean magnitude of the first decoded LLR and to combine a LLR for each bit in the second decoded LLR and divide by a second number of bits in the second decoded LLR to determine the second magnitude of the first decoded LLR.

4. The apparatus of claim 2, wherein the control unit is further configured to terminate decoding of the received code word when the mean magnitude of the first decoded LLR and the second decoded LLR are less than the mean magnitude of the previous first decoded LLR and the previous second decoded LLR, respectively.

5. The apparatus of claim 1, wherein the control unit is farther configured to compare the measure of the first decoded LLR to the previous measure of the first decoded LLR and to compare the measure of the second decoded LLR to the previous measure of the second decoded LLR after predetermined number of initial half iterations.

6. The apparatus of claim 1, where the first decoded LLR and the second decoded LLR of each bit in the received code word is calculated as follows:
$$LLR = log ( \frac{P ( 1 )}{P ( 0 )} ) ,$$
where P(1) represents a probability of a bit from the received code word is a logical one and P(0) represents a probability of a bit from the received code word is a logical zero.

7. An apparatus for decoding a received code word, comprising:
a decoder configured to provide decoded log likelihood ratio (LLR) based upon the received code word, a parity sequence, and extrinsic information; and
a control unit configured to compare a mean magnitude of the decoded LLR to a mean magnitude of a previous decoded LLR and to terminate decoding of the received code word when the mean magnitude of the first decoded LLR is less than the mean magnitude of the previous decoded LLR.

8. The apparatus of claim 7, where the first decoded LLR of each bit in the received code word is calculated as follows:
$$LLR = log ( \frac{P ( 1 )}{P ( 0 )} ) ,$$
where P(1) represents a probability of a bit from the received code word is a logical one and P(0) represents a probability of a bit from the received code word is a logical zero.

9. The apparatus of claim 7, wherein the control unit is further configured to combine a LLR for each bit in the decoded LLR and divide by a number of bits in the first decoded LLR to determine the mean magnitude of the decoded LLR.

10. The apparatus of claim 7, wherein the control unit is further configured to cause the decoder to use the decoded LLR as the received code word to determine another decoded LLR when the mean magnitude of the decoded LLR is greater than or equal to the mean magnitude of the previous decoded LLR.

11. The apparatus of claim 7, wherein the control unit is further configured to determine whether the mean magnitude of the decoded LLR is less than the mean magnitude of the previous decoded LLR for a predetermined number of times and to request termination of the decoding of the received code word when the mean magnitude of the decoded LLR is less than the mean magnitude of the previous first decoded LLR in excess of the predetermined number of times.

12. The apparatus of claim 7, wherein the control unit is further configured to request re-transmission of the received code word upon termination of its decoding.

13. A method for decoding a received code word, comprising:
(a) providing, by a receiver, a first decoded log likelihood ratio (LLR) and first extrinsic information based upon the received code word, a first party sequence, and second extrinsic information;
(b) providing, by the receiver, a second decoded LLR and the second extrinsic information based upon the received code word, a second parity sequence, and the first extrinsic information;
(c) comparing, by the receiver, a mean magnitude of the first decoded LLR and the second decoded LLR to a mean magnitude of a previous first decoded LLR and a previous second decoded LLR, respectively; and
(d) terminating, by the receiver, decoding of the received code word when the mean magnitude of the first decoded LLR and the second decoded LLR are less than the mean magnitude of the previous first decoded LLR and the previous second decoded LLR, respectively.

14. The method of claim 13, where the first decoded LLR and the second decoded LLR of each bit in the received code word is calculated as follows:
$$LLR = log ( \frac{P ( 1 )}{P ( 0 )} ) ,$$
where P(1) represents a probability of a bit from the received code word is a logical one and P(0) represents a probability of a bit from the received code word is a logical zero.

15. The method of claim 13, wherein step (c) comprises:
(c)(i) combining a LLR for each bit in the first decoded LLR and divide by a first number of bits in the first decoded LLR to determine the mean magnitude of the first decoded LLR; and
(c)(ii) combining a LLR for each bit in the second decoded LLR and divide by a second number of bits in the second decoded LLR to determine the second magnitude of the first decoded LLR.

16. The method of claim 13, further comprising:
(e) repeating step (a) and (b) with the first decoded LLR and the second decoded LLR, respectively, as the received code word to determine another first and second decoded LLR when the mean magnitude of the first and second decoded LLRs are greater than or equal to the mean magnitude of the previous first and second decoded LLRs.

17. The method of claim 13, wherein step (d) comprises:
(d)(i) determining whether the mean magnitude of the first decoded LLR and the second decoded LLR are less than the mean magnitude of the previous first decoded LLR and the previous second decoded LLR, respectively, for a predetermined number of times; and
(d)(ii) requesting termination of the decoding of the received code word when the mean magnitude of the first decoded LLR and the second decoded LLR are less than the mean magnitude of the previous first decoded LLR and the previous second decoded LLR, respectively, in excess of the predetermined number of times.

18. The method of claim 13, further comprising:
(e) requesting re-transmission of the received code word upon termination of its decoding.
